(19) United States
(12) Patent Application Publication
(10) Pub. No.: US 2006/0145598 A1
(43) Pub. Date: Jul. 6, 2006

(54) Electronic devices and process for forming the same

(76) Inventors: Charles Douglas MacPherson, Santa Barbara, CA (US); Dennis Damon Walker, Santa Barbara, CA (US); Matthew Stainer, Goleta, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/026,264

(22) Filed: Dec. 30, 2004

(51) Int. Cl. H01L 51/00

(52) U.S. Cl. 313/504

(57) ABSTRACT

An electronic device includes a substrate and a structure overlying the substrate and defining an array of openings arranged in a set of vectors. At first locations between openings along a first vector of the set of vectors, first heights at the first locations are substantially equal to one another. The electronic device also includes an organic layer in the geometric shape of a line that at least partially lies within the openings along the first vector and overlies the structure at the locations between the openings along the first vector.

### BACKGROUND OF THE INVENTION

1. Field of the Invention

This invention relates in general to electronic devices and processes for forming the same, and more specifically, to electronic devices including lines that include an organic layer and processes for forming such electronic devices.

2. Description of the Related Art

Electronic devices, including organic electronic devices, continue to be more extensively used in everyday life. Examples of organic electronic devices include Organic Light-Emitting Diodes (“OLEDs”). A variety of deposition techniques can be used in forming layers used in OLEDs. Techniques for printing layers include ink-jet printing and continuous printing.

Ink-jet printing has been used extensively in the formation of full-color OLED displays due to its ability to dispense precise amounts of liquid. However, ink-jet printers may not be capable of printing the narrowest of lines. Ink-jet printers dispense liquids as drops. A 40 pL drop can be used, but has a diameter of approximately 41 microns. Even when using state-of-the-art ink-jet technology, a 10 pL drop has a diameter of approximately 26 microns. In addition to having a limited ability to print fine lines, a printing head for an ink-jet printer moves at a rate no greater than approximately 0.1 m/s. A typical printing speed is approximately 0.064 m/s. As a result, ink-jet printing is time consuming, leading to limited throughput of devices.

Such low flow rate and drop-based methods of depositing organic layers have typically been used to avoid overflow of liquid compositions into adjacent openings of well structures associated with different colors in display devices. Overflow or bleeding of liquid compositions may reduce performance or change the color produced by adjacent electronic components.

However, as the number of organic electronic components in a device increases either through an increase in resolution or device surface area, the length of time used by typical ink jet deposition increases, leading to reduced throughput and, thus increased cost.

### SUMMARY OF THE INVENTION

An electronic device includes a substrate and a structure overlying the substrate and defining an array of openings arranged in a set of vectors. At first locations between openings along a first vector of the set of vectors, first heights at the first locations are substantially equal to one another. The electronic device also includes a line including an organic layer that at least partially lies within the openings along the first vector and overlies the structure at the locations between the openings along the first vector.

A process for forming an electronic device includes forming a structure overlying a substrate. The structure defines an array of openings arranged in a set of vectors, wherein, at first locations between openings along a first vector of the set of vectors, first heights at the first locations are substantially equal to one another. The process further includes printing a first line comprising a first organic layer, wherein the first line at least partially lies within the openings along the first vector and overlies the structure at the locations between openings along the first vector.

An electronic device includes a substrate and a first vector of openings defined by a first set of structures overlying the substrate. The first set of structures has first heights that are substantially equal to one another. The electronic device further includes a first line including a first organic layer that at least partially lies within the first vector of openings and overlies the first set of structures. The electronic device also includes a second vector of openings defined by a second set of structures and lying substantially parallel to the first vector of openings. The second set of structures has second heights that are substantially equal to one another. The electronic device also includes a second line including a second organic layer that at least partially lies within the second vector of openings and overlies the second set of structures.

The foregoing general description and the following detailed description are exemplary and explanatory only and are not restrictive of the invention, as defined in the appended claims.

### BRIEF DESCRIPTION OF THE DRAWINGS

The invention is illustrated by way of example and not limitation in the accompanying figures.

FIGS. 1 and 2 include a perspective view and a cross-sectional view, respectively, illustration that include portions of a substrate during a process in forming an exemplary electronic device, wherein a structure overlies the substrate and defines the set of openings.

FIG. 3 includes a cross-sectional view illustration during a dispensing process in forming the exemplary electronic device.

FIGS. 4 and 5 include cross-sectional view illustrations after printing an organic layer in the geometric shape of a line for the exemplary electronic device illustrated in FIG. 1.

FIGS. 6 and 7 include a plan view and a cross-sectional view, respectively, illustration after forming additional organic layers in the geometric shapes of lines and a second electrode over the substrate of FIGS. 4 and 5.

FIG. 8 includes a perspective view illustration of an alternative structure that includes transverse portions having different heights.

FIG. 9 includes a perspective view illustration of an alternative printing pattern that can be used in forming an electronic device.

### DETAILED DESCRIPTION

In one embodiment, an electronic device includes a substrate and a structure overlying the substrate and defining an array of openings arranged in a set of vectors. At first locations between openings along a first vector of the set of vectors, first heights at the first locations are substantially equal to one another. The electronic device also includes an organic layer in the geometric shape of a line that at least partially lies within the openings along the first vector and overlies the structure at the locations between the openings along the first vector.

In one example, the structure is a well structure. The electronic device may include a radiation-emitting component, a radiation-responsive component, or a combination thereof.

In another example, the organic layer includes an organic active layer. In a further example, the organic layer includes a charge-injecting layer, a charge-transport layer, a charge-blocking layer or any combination thereof.

At second locations between openings along a second vector of the set of second vectors, second heights at the second locations may be substantially equal to one another. The first heights and the second heights may be substantially equal to one another or the first heights may be significantly different from the second heights. In one example, the first vector and the second vector are oriented substantially perpendicular to each other.

In a further example, the electronic device includes an electrode lying between the substrate and the structure. In another example, the electronic device includes an electrode overlying the organic layer.

In another embodiment, a process for forming an electronic device includes forming a structure overlying a substrate. The structure defines an array of openings arranged in a set of vectors, wherein, at first locations between openings along a first vector of the set of vectors, first heights at the first locations are substantially equal to one another. The process further includes printing a first organic layer in the geometric shape of a first line, wherein the first organic layer at least partially lies within the openings along the first vector and overlies the structure at the locations between openings along the first vector.

In one example, the first organic layer includes an organic active layer. Printing may be performed as continuous printing using a continuous liquid dispense apparatus. Continuously printing the first organic layer may be performed at a travel velocity of greater than 100 cm/s.

In another example, the structure includes a second vector of the set of vectors and, at second locations between openings along the second vector, second heights at the second locations are substantially equal to one another. The process further includes continuously printing a second organic layer in the geometric shape of a second line. The second organic layer at least partially lies within the openings along the second vector and overlies the structure at locations between the openings along the second vector. The first organic layer may include a first organic active layer having an emission maximum at a first wavelength and the second organic layer may include a second organic active layer having an emission maximum at a second wavelength different from the first wavelength.

In a further embodiment, an electronic device includes a substrate and a first vector of openings defined by a first set of structures overlying the substrate. The first set of structures has first heights that are substantially equal to one another. The electronic device further includes a first organic layer in the geometric shape of a first line that at least partially lies within the first vector of openings and overlies the first set of structures. The electronic device also includes a second vector of openings defined by a second set of structures and lying substantially parallel to the first vector of openings. The second set of structures has second heights that are substantially equal to one another. The electronic device also includes a second organic layer in the geometric shape of a second line that at least partially lies within the second vector of openings and overlies the second set of structures.

In one example, the first heights are significantly different from the second heights. In another example, the first organic layer includes a first organic active layer having an emission maximum at a first wavelength, and the second organic layer includes a second organic active layer having an emission maximum at a second wavelength different from the first wavelength.

Other features and advantages of the invention will be apparent from the following detailed description, and from the claims. The detailed description first addresses Definitions and Clarification of Terms, followed by Process for Forming an Electronic Device, Alternative Embodiments, and Advantages.

1. Definitions and Clarification of Terms

Before addressing details of embodiments described below, some terms are defined or clarified. The terms “array,” “peripheral circuitry” and “remote circuitry” are intended to mean different areas or components of the organic electronic device. For example, an array may include pixels, cells, or other structures within an orderly arrangement (usually designated by columns and rows). The pixels, cells, or other structures within the array may be controlled locally by peripheral circuitry, which may lie within the same organic electronic device as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “charge-blocking,” when referring to a layer, material, member, or structure, is intended to mean such layer, material, member or structure significantly reduces the likelihood that a charge intermixes with another layer, material, member or structure.

The term “charge-injecting,” when referring to a layer, material, member, or structure, is intended to mean such layer, material, member or structure promotes charge migration into an adjacent layer, material, member or structure.

The term “charge-transport,” when referring to a layer, material, member or structure, is intended to mean such layer, material, member or structure facilitates migration of such charge through the thickness of such layer, material, member or structure with relative efficiency and small loss of charge.

The term “continuous” and its variants are intended to mean substantially unbroken. In one embodiment, continuously printing is printing using a substantially unbroken stream of a liquid or a liquid composition, as opposed to a depositing technique using drops. In another embodiment, extending continuously refers to a length of a layer, member, or structure in which no significant breaks in the layer, member, or structure lie along its length.

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors connected to different electronic components where a capacitor between the conductors is unintended or incidental).

The term “electronic device” is intended to mean a collection of circuits, electronic components, or combinations thereof that collectively, when properly connected and supplied with the appropriate potential(s), performs a function. An electronic device may include or be part of a system. An example of an electronic device includes a display, a sensor array, a computer system, an avionics system, an automobile, a cellular phone, another consumer or industrial electronic product, or the like.

The terms “height,” “length,” and “width,” when referring to a structure overlying a substrate, are intended to refer to dimensions substantially perpendicular to each other. “Height” is intended to refer to a distance above an underlying substrate. “Length” is intended to refer to a dimension within a plane substantially parallel to the substrate. “Width” is intended to refer to a dimension within a plane substantially parallel to the substrate and substantially perpendicular to the “length” dimension. In one embodiment, the “width” is shorter than the “length.”

The term “line,” when referring to printing over a substrate, is intended to mean an unbroken geometric element as seen by a plan view of the substrate. Note that a line may or may not have sharp angles.

The term “liquid composition” is intended to mean a material that is dissolved in a liquid medium to form a solution, dispersed in a liquid medium to form a dispersion, or suspended in a liquid medium to form a suspension or an emulsion.

The term “organic active layer” is intended to mean one or more organic layers, wherein at least one of the organic layers, by itself, or when in contact with a dissimilar material, is capable of forming a rectifying junction.

The term “opening” is intended to mean an area characterized by the absence of a particular structure that surrounds the area, as viewed from the perspective of a plan view.

The term “overlying” does not necessarily mean that a layer, member, or structure is immediately next to or in contact with another layer, member, or structure.

The term “radiation-emitting component” is intended to mean an electronic component, which when properly biased, emits radiation at a targeted wavelength or spectrum of wavelengths. The radiation may be within the visible-light spectrum or outside the visible-light spectrum (ultraviolet (“UV”) or infrared (“IR”). A light-emitting diode is an example of a radiation-emitting component.

The term “radiation-responsive component” is intended to mean an electronic component, which when properly biased, can sense or respond to radiation at a targeted wavelength or spectrum of wavelengths. The radiation may be within the visible-light spectrum or outside the visible-light spectrum (UV or IR). Photodetectors, IR sensors, biosensors, and photovoltaic cells are examples of radiation-responsive components.

The term “rectifying junction” is intended to mean a junction within a semiconductor layer or a junction formed by an interface between a semiconductor layer and a dissimilar material, in which charge carriers of one type flow easier in one direction through the junction compared to the opposition direction. A pn junction is an example of a rectifying junction that can be used as a diode.

The term “stitching defect” is intended to mean a fabrication artifact in an electronic device, wherein the fabrication artifact appears as a seam or other pattern within the electronic device that can be observed when the electronic device is fabricated, used, or a combination thereof.

The term “structure” is intended to mean one or more patterned layers or members, which by itself or in combination with other patterned layer(s) or member(s), forms a unit that serves an intended purpose. Examples of structures include electrodes, well structures, cathode separators, and the like.

The term “substantially equal” is intended to mean that two or more values of a parameters are equal or almost equal such that any inequality is considered to be insignificant to one of ordinary skill in the art.

The term “substantially parallel” is intended to mean that the orientations of a combination of one or more lines, one or more vectors, or one or more planes are parallel or almost parallel such that any skewness is considered to be insignificant to one of ordinary skill in the art.

The term “substrate” is intended to mean a base material that can be either rigid or flexible and may include one or more layers of one or more materials, which can include glass, polymer, a metal or ceramic material, or any combination thereof. The reference point for a substrate is the beginning point of a process sequence. The substrate may or may not include electronic components, circuits, or conductive members.

The term “travel velocity” is intended to mean a rate of movement along a given axis.

The term “vector” when associated with an array is intended to mean a row, column, or diagonal line.

The term “well structure” is intended to mean a structure overlying a substrate, wherein the structure serves a principal function of separating an object, a region, or any combination thereof within or overlying the substrate from contacting a different object or different region within or overlying the substrate.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Group numbers corresponding to columns within the Periodic Table of the elements use the “New Notation” convention as seen in the CRC Handbook of Chemistry and Physics, 81st Edition (2000).

Unless otherwise defined, all technical and scientific terms used herein have the same meaning as commonly understood by one of ordinary skill in the art to which this invention belongs. Although suitable methods and materials are described herein for embodiments of the invention, or methods for making or using the same, other methods and materials similar or equivalent to those described can be used without departing from the scope of the invention. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

To the extent not described herein, many details regarding specific materials, processing acts, and circuits are conventional and may be found in textbooks and other sources within the organic light-emitting diode display, photodetector, photovoltaic, and semiconductor arts.

2. Process for Forming an Electronic Device

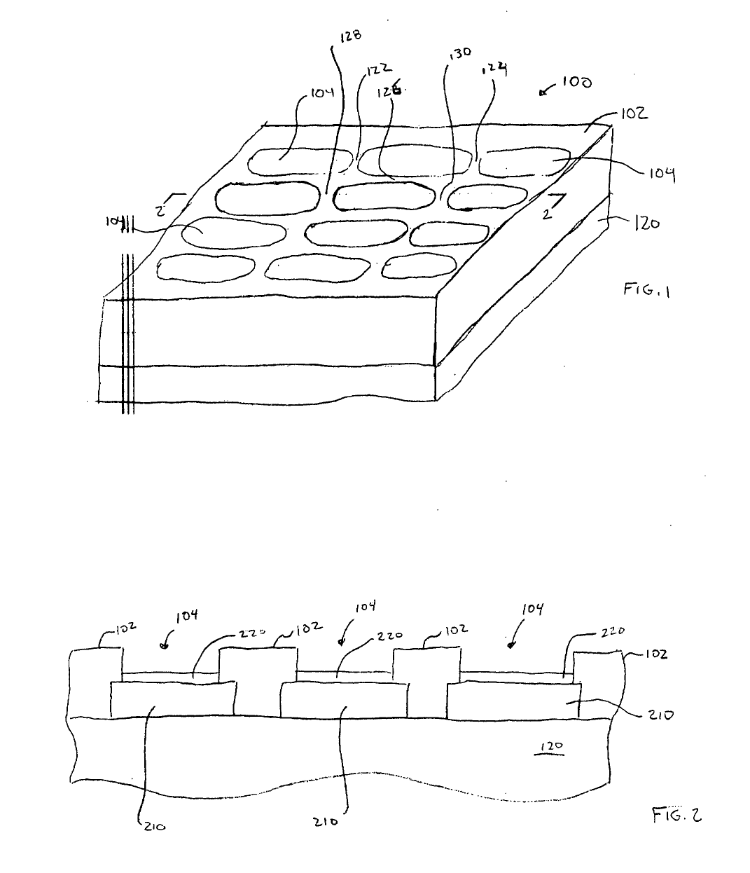

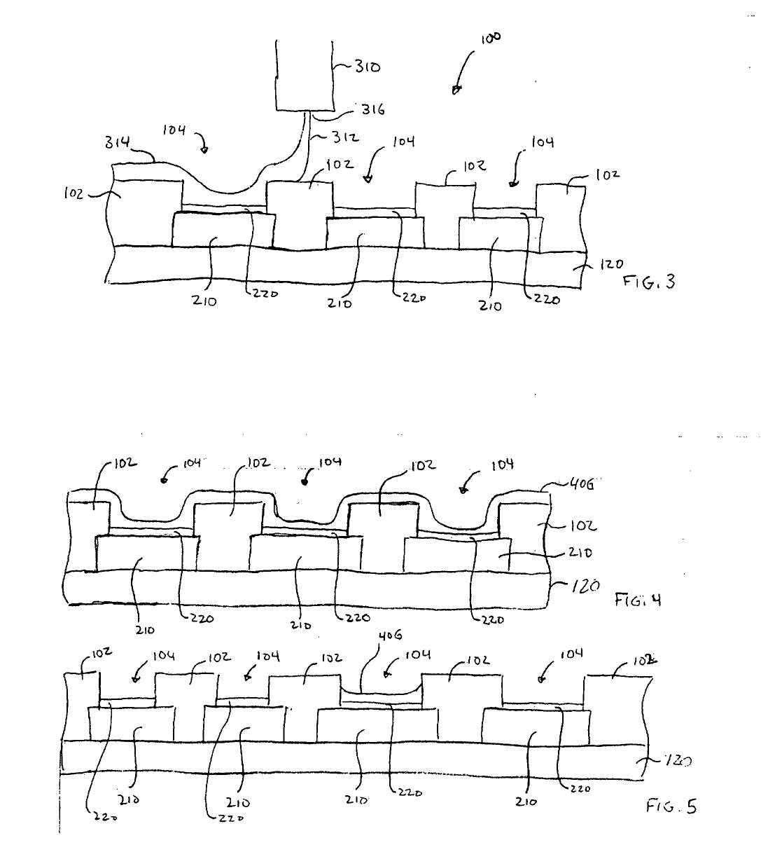

FIGS. 1-7 include illustrations during the formation of an exemplary electronic device including the workpiece 100. FIGS. 1-2 include illustrations of perspective and cross-sectional views, respectively, during an early portion of a fabrication sequence. First electrodes 210 are formed over a substrate 120. The substrate 120 is conventional, can include an organic or inorganic material, and may be rigid or flexible. The substrate 120 may or may not include one or more electronic components. In one embodiment, the first electrodes 210 are anodes for the electronic components illustrated. In one embodiment, the substrate 120 and first electrodes 210 are formed using one or more conventional techniques. Each of the layer(s) within the first electrodes 210 is deposited and may or may not need to be patterned. In one embodiment, the first electrodes 210 are substantially transparent to the targeted radiation wavelength or spectrum (spectra) of wavelengths to which the electronic component emits or responds.

A substrate structure 102 is formed and overlies the substrate 120 and portions of the first electrodes 210, and the substrate structure 102 is configured to define an array of openings 104. In one embodiment, the structure 102 is a well structure. The array of openings 104 includes vectors of openings 104 that expose portions of the first electrodes 210. Each vector can be a row or a column of openings 104. Locations of the substrate structure 102, between the openings 104 along a particular vector, have heights that are substantially equal to one another. For example, the substrate structure 102 can be formed such that along a row, heights at locations between the openings 104, such as the locations 122 and 124, are substantially equal to one another.

In one exemplary embodiment, the heights at locations between openings along a first vector, such as a row (e.g., locations 122 and 124), are substantially equal to heights at locations along a second vector, such as a column (e.g., location 126). In alternative embodiments, the heights at locations along the second vector may be different from those at locations along the first vector. For example, heights at locations (e.g., locations 122 and 124) along a first vector, such as a first row, are substantially equal to one another. Heights at locations along a second vector (e.g., locations 128 and 130), such as a second row, are also substantially equal to one another. However, the heights at the locations along the first vector (e.g., locations 122 and 124) can be different from the heights at the locations along the second vector (e.g., locations 128 and 130).

In a specific embodiment, the substrate structure 102 includes an inorganic (e.g., silicon dioxide, silicon nitride, aluminum oxide, aluminum nitride, etc.), an organic material (e.g., photoresist, polyimide, etc.), or any combination thereof. In another embodiment, the substrate structure 102 can include a black material (e.g., carbon) in order to increase contrast to ambient light while the electronic device is being operated. In one exemplary embodiment, the substrate structure 102 may be formed from one or more resist or polymeric layers. The resist may, for example, be a negative resist material or positive resist material. The resist may be deposited over the substrate 120 and first electrodes 210 using a conventional technique. The substrate structure 102 may be patterned as deposited or may be deposited as a blanket layer and patterned using a conventional lithographic technique. In one particular embodiment, the substrate structure 102 has a thickness between approximately 2 to 10 microns as viewed from a cross-sectional view. In one exemplary embodiment, the openings 104 are in a range of approximately 50 to 100 microns wide and in a range of approximately 100 to 500 microns long when viewed from a plan view. The slope of the substrate structure 102 at the openings 104 may be less than 90°, approximately 90°, or more than 90° with respect to the surface of the first electrodes 210.

In one embodiment, the substrate structure 102 may or may not receive a surface treatment before forming an organic layer. A conventional fluorination surface treatment may be performed to reduce the surface energy of the substrate structure 102.

An optional layer 220, such as a charge-injecting layer, a charge-blocking layer, a charge-transport layer, or a combination thereof is deposited to overlie the first electrodes 210. In one embodiment, the optional layer 220 includes a hole-injecting layer, a hole-transport layer, an electron-blocking layer, or any combination thereof. The optional layer 220 is formed by one or more conventional techniques. For example, the optional layer 220 is deposited and may or may not need to be patterned. In one embodiment, the optional layer 220 may be formed from a liquid composition using the printing apparatus as described in more detail below.

At this point in the process, one or more layers can be formed using a printing apparatus. The printing apparatus can print one or more line(s) having the same or different compositions. In one embodiment, the printing apparatus prints a liquid composition in the form of a line that comprises an organic layer. Exemplary organic layers include organic active layers, charge-injecting layers, charge-transport layers, charge-blocking layers, or a combination thereof. Liquid compositions used for forming such layers are described below.

In some embodiments, the liquid composition includes at least one organic solvent and at least one material. For example, the liquid composition may include a solvent and between approximately 0.5 and 5 weight % solids, such as between approximately 1 weight % and 2 weight % solids. The solids may include small organic molecules, polymers, or combinations thereof.

For a radiation-emitting organic active layer, suitable radiation-emitting materials include one or more small molecule materials, one or more polymeric materials, or a combination thereof. A small molecule material may include any one or more of those described in, for example, U.S. Pat. No. 4,356,429 (“Tang”); U.S. Pat. No. 4,539,507 (“Van Slyke”); U.S. Patent Application Publication No. US 2002/0121638 (“Grushin”); or U.S. Pat. No. 6,459,199 (“Kido”). Alternatively, a polymeric material may include any one or more of those described in U.S. Pat. No. 5,247,190 (“Friend”); U.S. Pat. No. 5,408,109 (“Heeger”); or U.S. Pat. No. 5,317,169 (“Nakano”). An exemplary material is a semiconducting conjugated polymer. An example of such a polymer includes poly(paraphenylenevinylene) (PPV), a PPV copolymer, a polyfluorene, a polyphenylene, a polyacetylene, a polyalkylthiophene, poly(n-vinylcarbazole) (PVK), or the like. In one specific embodiment, a radiation-emitting active layer without any guest material may emit blue light.

For a radiation-responsive organic active layer, a suitable radiation-responsive material may include many a conjugated polymer or an electroluminescent material. Such a material includes, for example, a conjugated polymer or an electro- and photo-luminescent material. A specific example includes poly(2-methoxy,5-(2-ethyl-hexyloxy)-1,4-phenylene vinylene) (“MEH-PPV”) or a MEH-PPV composite with CN-PPV.

The location of a filter layer may be between an organic active layer and a user side of the electronic device. A filter layer may be part of a substrate, an electrode (e.g., an anode or a cathode), a charge-transport layer, a charge-injecting layer, or a charge-blocking layer; the filter layer may lie between any one or more of the substrate, an electrode, a charge-transport layer, a charge-injecting layer, a charge-blocking layer, or any combination thereof; or any combination thereof. In another embodiment, the filter layer may be a layer that is fabricated separately (while not attached to the substrate) and later attached to the substrate at any time before, during, or after fabricating the electronic components within the electronic device. In this embodiment, the filter layer may lie between the substrate and a user of the electronic device.

When the filter layer is separate from or part of the substrate, or when the filter lies between the substrate and an electrode closest to the substrate, a suitable material includes an organic material including a polyolefin (e.g., polyethylene or polypropylene); a polyester (e.g., polyethylene terephthalate or polyethylene naphthalate); a polyimide; a polyamide; a polyacrylonitrile or a polymethacrylonitrile; a perfluorinated or partially fluorinated polymer (e.g., polytetrafluoroethylene or a copolymer of tetrafluoroethylene and polystyrene); a polycarbonate; a polyvinyl chloride; a polyurethane; a polyacrylic resin, including a homopolymer or a copolymer of an ester of an acrylic or methacrylic acid; an epoxy resin; a Novolac resin; or any combination thereof.

For a hole-injecting layer, hole-transport layer, electron-blocking layer, or any combination thereof, a suitable material includes polyaniline (“PANI”), poly(3,4-ethylenedioxythiophene) (“PEDOT”), polypyrrole, an organic charge transfer compound, such as tetrathiafulvalene tetracyanoquinodimethane (“TTF-TCQN”), a hole-transport material as described in Kido, or any combination thereof.

For an electron-injecting layer, electron transport layer, hole-blocking layer, or any combination thereof, a suitable material includes a metal-chelated oxinoid compound (e.g., Alq₃ or aluminum(III)bis(2-methyl-8-quinolinato)4-phenylphenolate (“BAlq”)); a phenanthroline-based compound (e.g., 2,9-dimethyl-4,7-diphenyl-1,10-phenanthroline (“DDPA”) or 9,10-diphenylanthracence (“DPA”)); an azole compound (e.g., 2-tert-butylphenyl-5-biphenyl-1,3,4-oxadiazole (“PBD”) or 3-(4-biphenyl)-4-phenyl-5-(4-t-butylphenyl)-1,2,4-triazole (“TAZ”); an electron transport material as described in Kido; a diphenylanthracene derivative; a dinaphthylanthracene derivative; 4,4-bis(2,2-diphenyl-ethen-1-yl)-biphenyl (“DPVBI”); 9,10-di-beta-naphthylanthracene; 9,10-di-(naphenthyl)anthracene; 9,10-di-(2-naphthyl)anthracene (“ADN”); 4,4′-bis(carbazol-9-yl)biphenyl (“CBP”); 9,10-bis-[4-(2,2-diphenylvinyl)-phenyl]-anthracene (“BDPVPA”); anthracene, N-arylbenzimidazoles (such as “TPBI”); 1,4-bis[2-(9-ethyl-3-carbazoyl)vinylenyl]benzene; 4,4′-bis[2-(9-ethyl-3-carbazoyl)vinylenyl]-1,1′-biphenyl; 9,10-bis[2,2-(9,9-fluorenylene)vinylenyl]anthracene; 1,4-bis[2,2-(9,9-fluorenylene)vinylenyl]benzene; 4,4′-bis[2,2-(9,9-fluorenylene)vinylenyl]-1,1′-biphenyl; perylene, substituted perylenes; tetra-tert-butylperylene (“TBPe”); bis(3,5-difluoro-2-(2-pyridyl)phenyl-(2-carboxypyridyl) iridium III (“F(Ir)Pic”); a pyrene, a substituted pyrene; a styrylamine; a fluorinated phenylene; oxidazole; 1,8-naphthalimide; a polyquinoline; one or more carbon nanotubes within PPV; or any combination thereof.

For an electronic component, such as a resistor, transistor, capacitor, etc., the organic layer may include one or more of thiophenes (e.g., polythiophene, poly(alkylthiophene), alkylthiophene, bis(dithienthiophene), alkylanthradithiophene, etc.), polyacetylene, pentacene, phthalocyanine, or any combination thereof.

An example of an organic dye includes 4-dicyanmethylene-2-methyl-6-(p-dimethyaminostyryl)-4H-pyran (DCM), coumarin, pyrene, perylene, rubrene, a derivative thereof, or any combination thereof.

An example of an organometallic material includes a functionalized polymer comprising one or more functional groups coordinated to at least one metal. An exemplary functional group contemplated for use includes a carboxylic acid, a carboxylic acid salt, a sulfonic acid group, a sulfonic acid salt, a group having an OH moiety, an amine, an imine, a diimine, an N-oxide, a phosphine, a phosphine oxide, a β-dicarbonyl group, or any combination thereof. An exemplary metal contemplated for use includes a lanthanide metal (e.g., Eu, Tb), a Group 7 metal (e.g., Re), a Group 8 metal (e.g., Ru, Os), a Group 9 metal (e.g., Rh, Ir), a Group 10 metal (e.g., Pd, Pt), a Group 11 metal (e.g., Au), a Group 12 metal (e.g., Zn), a Group 13 metal (e.g., Al), or any combination thereof. Such an organometallic material includes a metal chelated oxinoid compound, such as tris(8-hydroxyquinolato)aluminum (Alq₃); a cyclometalated iridium or platinum electroluminescent compound, such as a complex of iridium with phenylpyridine, phenylquinoline, or phenylpyrimidine ligands as disclosed in published PCT Application WO 02/02714, an organometallic complex described in, for example, published applications US 2001/0019782, EP 1191612, WO 02/15645, WO 02/31896, and EP 1191614; or any mixture thereof.

An example of a conjugated polymer includes a poly(phenylenevinylene), a polyfluorene, a poly(spirobifluorene), a copolymer thereof, or any combination thereof.

Selecting a liquid medium can also be an important factor for achieving one or more proper characteristics of the liquid composition. A factor to be considered when choosing a liquid medium includes, for example, viscosity of the resulting solution, emulsion, suspension, or dispersion, molecular weight of a polymeric material, solids loading, type of liquid medium, boiling point of the liquid medium, temperature of an underlying substrate, thickness of an organic layer that receives a guest material, or any combination thereof

In some embodiments, the liquid medium includes at least one solvent. An exemplary organic solvent includes a halogenated solvent, a colloidal-forming polymeric acid, a hydrocarbon solvent, an aromatic hydrocarbon solvent, an ether solvent, a cyclic ether solvent, an alcohol solvent, a glycol solvent, a ketone solvent, a nitrile solvent, a sulfoxide solvent, an amide solvent, or any combination thereof.

An exemplary halogenated solvent includes carbon tetrachloride, methylene chloride, chloroform, tetrachloroethylene, chlorobenzene, bis(2-chloroethyl)ether, chloromethyl ethyl ether, chloromethyl methyl ether, 2-chloroethyl ethyl ether, 2-chloroethyl propyl ether, 2-chloroethyl methyl ether, or any combination thereof.

An exemplary colloidal-forming polymeric acid includes a fluorinated sulfonic acid (e.g., fluorinated alkylsulfonic acid, such as perfluorinated ethylenesulfonic acid) or any combinations thereof.

An exemplary hydrocarbon solvent includes pentane, hexane, cyclohexane, heptane, octane, decahydronaphthalene, a petroleum ether, ligroine, or any combination thereof.

An exemplary aromatic hydrocarbon solvent includes benzene, naphthalene, toluene, xylene, ethyl benzene, cumene (iso-propyl benzene) mesitylene (trimethyl benzene), ethyl toluene, butyl benzene, cymene (iso-propyl toluene), diethylbenzene, iso-butyl benzene, tetramethyl benzene, sec-butyl benzene, tert-butyl benzene, anisole, 4-methylanisole, 3,4-dimethylanisole, or any combination thereof.

An exemplary ether solvent includes diethyl ether, ethyl propyl ether, dipropyl ether, diisopropyl ether, dibutyl ether, methyl t-butyl ether, glyme, diglyme, benzyl methyl ether, isochroman, 2-phenylethyl methyl ether, n-butyl ethyl ether, 1,2-diethoxyethane, sec-butyl ether, diisobutyl ether, ethyl n-propyl ether, ethyl isopropyl ether, n-hexyl methyl ether, n-butyl methyl ether, methyl n-propyl ether, or any combination thereof.

An exemplary cyclic ether solvent includes tetrahydrofuran, dioxane, tetrahydropyran, 4 methyl-1,3-dioxane, 4-phenyl-1,3-dioxane, 1,3-dioxolane, 2-methyl-1,3-dioxolane, 1,4-dioxane, 1,3-dioxane, 2,5-dimethoxytetrahydrofuran, 2,5-dimethoxy-2,5-dihydrofuran, or any combination thereof.

An exemplary alcohol solvent includes methanol, ethanol, 1-propanol, 2-propanol, 1-butanol, 2-butanol, 2-methyl-1-propanol (i.e., iso-butanol), 2-methyl-2-propanol (i.e., tert-butanol), 1-pentanol, 2-pentanol, 3-pentanol, 2,2-dimethyl-1-propanol, 1-hexanol, cyclopentanol, 3-methyl-1-butanol, 3-methyl-2-butanol, 2-methyl-1-butanol, 2,2-dimethyl-1-propanol, 3-hexanol, 2-hexanol, 4-methyl-2-pentanol, 2-methyl-1-pentanol, 2-ethylbutanol, 2,4-dimethyl-3-pentanol, 3-heptanol, 4-heptanol, 2-heptanol, 1-heptanol, 2-ethyl-1-hexanol, 2,6-dimethyl-4-heptanol, 2-methylcyclohexanol, 3-methylcyclohexanol, 4-methylcyclohexanol, or any combination thereof.

An alcohol ether solvent may also be employed. An exemplary alcohol ether solvent includes 1-methoxy-2-propanol, 2-methoxyethanol, 2-ethoxyethanol, 1-methoxy-2-butanol, ethylene glycol monoisopropyl ether, 1-ethoxy-2-propanol, 3-methoxy-1-butanol, ethylene glycol monoisobutyl ether, ethylene glycol mono-n-butyl ether, 3-methoxy-3-methylbutanol, ethylene glycol mono-tert-butyl ether, or any combination thereof.

An exemplary glycol solvent includes ethylene glycol, propylene glycol, propylene glycol monomethyl ether (PGME), dipropylene glycol monomethyl ether (DPGME), or any combination thereof.

An exemplary ketone solvent includes acetone, methylethyl ketone, methyl iso-butyl ketone, cyclohexanone, isopropyl methyl ketone, 2-pentanone, 3-pentanone, 3-hexanone, diisopropyl ketone, 2-hexanone, cyclopentanone, 4-heptanone, iso-amyl methyl ketone, 3-heptanone, 2-heptanone, 4-methoxy-4-methyl-2-pentanone, 5-methyl-3-heptanone, 2-methylcyclohexanone, diisobutyl ketone, 5-methyl-2-octanone, 3-methylcyclohexanone, 2-cyclohexen-1-one, 4-methylcyclohexanone, cycloheptanone, 4-tert-butylcyclohexanone, isophorone, benzyl acetone, or any combination thereof.

An exemplary nitrile solvent includes acetonitrile, acrylonitrile, trichloroacetonitrile, propionitrile, pivalonitrile, isobutyronitrile, n-butyronitrile, methoxyacetonitrile, 2-methylbutyronitrile, isovaleronitrile, N-valeronitrile, n-capronitrile, 3-methoxypropionitrile, 3-ethoxypropionitrile, 3,3′-oxydipropionitrile, n-heptanenitrile, glycolonitrile, benzonitrile, ethylene cyanohydrin, succinonitrile, acetone cyanohydrin, 3-n-butoxypropionitrile, or any combination thereof.

An exemplary sulfoxide solvent includes dimethyl sulfoxide, di-n-butyl sulfoxide, tetramethylene sulfoxide, methyl phenyl sulfoxide, or any combinations thereof.

An exemplary amide solvent includes dimethyl formamide, dimethyl acetamide, acylamide, 2-acetamidoethanol, N,N-dimethyl-m-toluamide, trifluoroacetamide, N, N-dimethylacetamide, N,N-diethyldodecanamide, epsilon-caprolactam, N, N-diethylacetamide, N-tert-butylformamide, formamide, pivalamide, N-butyramide, N,N-dimethylacetoacetamide, N-methyl formamide, N,N-diethylformamide, N-formylethylamine, acetamide, N,N-diisopropylformamide, 1-formylpiperidine, N-methylformanilide, or any combinations thereof.

A crown ether contemplated includes any one or more crown ethers that can function to assist in the reduction of the chloride content of an epoxy compound starting material as part of the combination being treated according to the invention. An exemplary crown ether includes benzo-15-crown-5; benzo-18-crown-6; 12-crown-4; 15-crown-5; 18-crown-6; cyclohexano-15-crown-5; 4′,4″(5″)-ditert-butyldibenzo-18-crown-6; 4′,4″(5″)-ditert-butyldicyclohexano-18-crown-6; dicyclohexano-18-crown-6; dicyclohexano-24-crown-8; 4′-aminobenzo-15-crown-5; 4′-aminobenzo-18-crown-6; 2-(aminomethyl)-15-crown-5; 2-(aminomethyl)-18-crown-6; 4′-amino-5′-nitrobenzo-15-crown-5; 1-aza-12-crown-4; 1-aza-15-crown-5; 1-aza-18-crown-6; benzo-12-crown-4; benzo-15-crown-5; benzo-18-crown-6; bis((benzo-15-crown-5)-15-ylmethyl)pimelate; 4-bromobenzo-18-crown-6; (+)-(18-crown-6)-2,3,11,12-tetra-carboxylic acid; dibenzo-18-crown-6; dibenzo-24-crown-8; dibenzo-30-crown-10; ar-ar′-di-tert-butyldibenzo-18-crown-6; 4′-formylbenzo-15-crown-5; 2-(hydroxymethyl)-12-crown-4; 2-(hydroxymethyl)-15-crown-5; 2-(hydroxymethyl)-18-crown-6; 4′-nitrobenzo-15-crown-5; poly-[(dibenzo-18-crown-6)-co-formaldehyde]; 1,1-dimethylsila-11-crown-4; 1,1-dimethylsila-14-crown-5; 1,1-dimethylsila-17-crown-5; cyclam; 1,4,10,13-tetrathia-7,16-diazacyclooctadecane; porphines; or any combination thereof.

In another embodiment, the liquid medium includes water. A conductive polymer complexed with a water-insoluble colloid-forming polymeric acid can be deposited over a substrate and used as a charge-transport layer.

Many different classes of liquid medium (e.g., halogenated solvents, hydrocarbon solvents, aromatic hydrocarbon solvents, water, etc.) are described above. Mixtures of more than one of the liquid medium from different classes may also be used.

The liquid composition may also include an inert material, such as a binder material, a filler material, or a combination thereof. With respect to the liquid composition, an inert material does not significantly affect the electronic, radiation emitting, or radiation responding properties of a layer that is formed by or receives at least a portion of the liquid composition.

The printing apparatus, including a print head 310, continuously prints a segment 314 over the substrate structure 102 and within the openings 104 in the form of a line as illustrated in FIG. 3. In one exemplary embodiment, a printing apparatus continuously prints the liquid composition within the openings 104 along a vector and at least in part over the substrate structure 102 at locations between the openings 104 and along the vector.

The printing head 310 includes the nozzle 316 through which a continuous stream 312 of the liquid composition is dispensed. In one embodiment, the printing head 310 is configured to continuously print the liquid composition onto the workpiece 100 including the substrate 120 and the substrate structure 102. The nozzle 316 has an opening that can be at least 10 microns wide. In one embodiment, the opening is in a range of approximately 10 to 30 microns wide. In one specific embodiment, the opening is approximately 18 microns wide. In another specific embodiment, the opening is approximately 12 microns wide or approximately 14 microns wide.

In one exemplary embodiment, the continuous stream 312 of liquid composition is printed along a vector (e.g., a row or a column) of openings 104. The printing head 310 is directed along the vector of openings 104, depositing the continuous stream 312 of liquid composition over the optional layer 220 within the openings 104 and, at least partially over the substrate structure 102 at locations between the openings 104 and along the vector. The viscosity of the liquid composition increases as its liquid medium evaporates from the segment 314.

The printing apparatus can be configured to print the continuous stream 312 of the liquid composition over the substrate 120 at a rate of at least 0.1 m/s. In another embodiment, the printing apparatus may be configured to print the segment 314 at a rate of at least 1 m/s, at least 3 m/s, or at least 6 m/s along the segment 314. In a particular embodiment, the liquid composition is deposited at a rate in a range of approximately 1 m/s to 3 m/s.

The printing head 310 may be configured to dispense the liquid composition at a rate of at least 10 microliters per minute, such as approximately 50 microliters/min., approximately 100 microliters/min. or higher. For example, the printing head 310 may dispense the liquid composition at a rate between approximately 50 to 400 microliters/min. The size of the opening for the nozzle 316 may be selected based on one or more conditions, one or more parameters of the continuous printing or any combination thereof. In one particular embodiment, the liquid composition is dispensed from the printing head 310 at a rate of approximately 100 microliters/min. through an opening of approximately 18 microns wide (e.g., diameter).

The liquid medium within the liquid composition (of the segment 314) evaporates to leave a first organic active layer 406 in a shape of a line as seen from a plan view. As illustrated in FIG. 4, the first organic active layer 406 lies over the optional layer 220 and the first electrodes 210, within the openings 104 and, in part, over the substrate structure 102. FIG. 5 illustrates a cross-sectional view of the substrate structure 102 and substrate 120 in a direction substantially perpendicular to the cross-sectional view in FIG. 4. For example, the cross-sectional view in FIG. 4 may be along a vector, such as a row, and the cross-sectional view in FIG. 5 may be along a different vector, such as a column.

As can be seen from FIGS. 4 and 5, the first organic active layer 406 is formed within the openings 104 located along a row. However, the first organic active layer 406 does not spill into openings located along adjacent rows. Along other rows, one or more other layers (not illustrated) including one or more organic layers may be subsequently formed from other liquid compositions. Those other layer(s) can be formed as segments within the openings 104 located along their respective rows and over the substrate structure 102 between the openings 104 located along that respective row without spilling into openings located along adjacent rows.

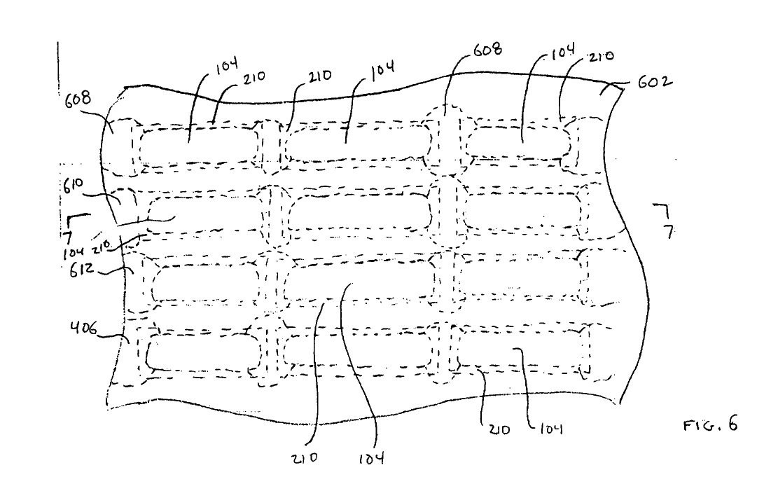

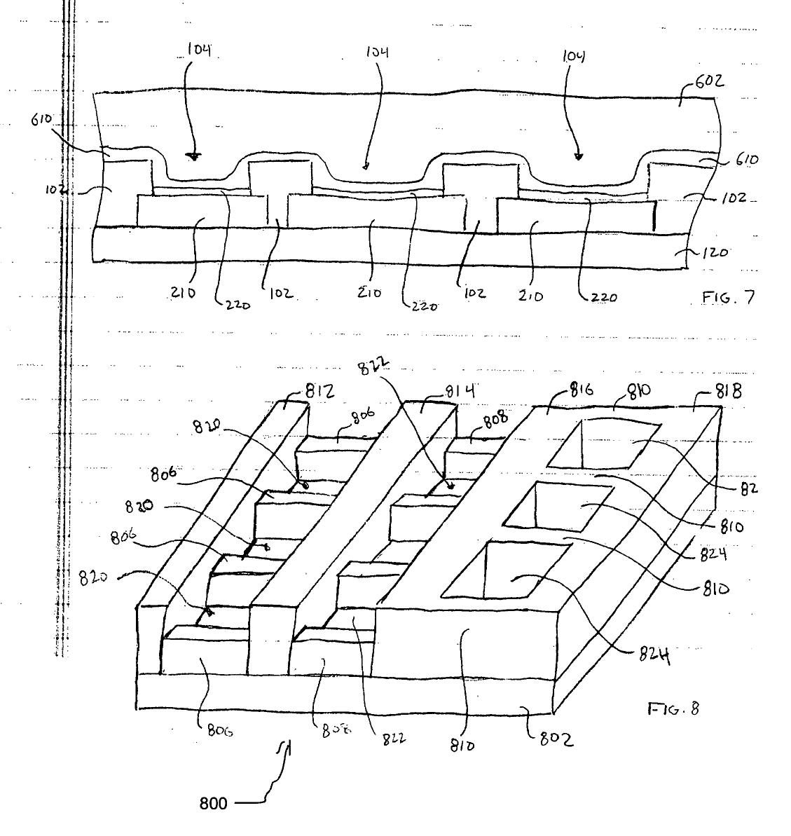

A second electrode 602 is formed over the substrate structure 102 and the first electrodes 210 as illustrated in FIGS. 6 and 7. In one embodiment, additional organic active layers 608, 610, and 612 have been printed. Each of the organic active layers 608, 610, and 612 can be formed using the printing apparatus and procedure previously described with respect to the first organic active layer 406. In one specific embodiment, the organic active layers 406 and 608 have substantially the same composition, and each of the organic active layers 610 and 612 have different compositions compared to the other layers illustrated in FIG. 6. For example, the organic active layers 406 and 608 may include a blue light-emitting layer, a second organic active layer 610 can include a green light-emitting layer, and a third organic active layer 612 can include a red light-emitting layer. In one example, one organic active layer, such as the organic active layer 610, has an emission maximum at a first wavelength and a second organic active layer, such as one of the organic active layers 610 and 612, has an emission maximum at a second wavelength different from the first wavelength. Over the substrate structure 102, any one or more of the organic active layers 406, 608, 610, or 612 may contact, underlie or overlie a different organic active layer. As long as any specific organic active layer does not lie along the bottom of an opening of an adjacent row, the electronic device can operate properly.

In one embodiment, the organic active layers 406, 608, 610, 612, or any combination thereof have a thickness in a range of approximately 10 to 100 nm as measured within a center of an opening within the well structure. The organic active layer 406, 608, 610, 612, or any combination thereof may be formed by printing a segment during a single pass or by using more than one pass. For example, if the solids concentration within the liquid composition is at least 2 weight %, the organic active layer can be formed by printing a segment on a single pass. If the solids concentration within the liquid composition is approximately 1 weight %, the organic active layer can be formed by printing more than one line on top of another segment using more than one pass. In one specific embodiment, the first organic active layer 406 can be formed by printing a first segment to a thickness of approximately 20 nm, and printing a second segment to a cumulative thickness of approximately 50 nm over the first segment. After reading this specification, skilled artisans will appreciate that other combinations of thicknesses can be used.

The organic active layer 406, 608, 610, 612, or any combination thereof can be cured after printing one or more of the layers. In one embodiment, the organic active layers 406, 608, 610, 612 can lie within an array of electronic components. The array comprises a first set of first electronic components lying closest to a first side of the array, and a second set of second electronic components lying closest to a second side of the array, wherein the second side is opposite the first side. The organic active layer 406, 608, 610, 612, or any combination thereof includes segment(s) that extend continuously from one of the first electronic components to one of the second electronic components.

Although not illustrated, a hole-blocking layer, an electron transport layer, an electron-injecting layer, or a combination thereof can be formed over the organic active layers 406, 608, 610, 612, or any combination thereof before forming the second electrode 602. The hole-blocking, electron transport, or electron-injecting layer can include one or more conventional materials, and may be formed using a conventional deposition technique. In one embodiment, the hole-blocking layer, electron transport layer, or electron-injecting layer can be formed by printing the layer using the printing apparatus.

A second electrode 602 overlies a set of the organic active layers 406, 608, 610, and 612. In one embodiment, the second electrode 602 is a common cathode for the electronic components being formed. The second electrode 602 includes materials conventionally used for cathodes within OLEDs. The second electrode 602 is formed using a conventional deposition technique.

Application of an electrical potential(s) across any one or more of the first electrodes 210 and the second electrode 602 can result in radiation emission from one or more organic active layers (e.g., layer 406, 608, 610, 612, or any combination thereof located between the first electrode(s) 210 and the second electrode 602. In one embodiment, the array is substantially free of a stitching defect.

Other circuitry not illustrated in FIGS. 6 and 7 may be formed using one or more of the previously described or additional layers. Although not illustrated, additional insulating layer(s) and interconnect level(s) may be formed to allow for circuitry in peripheral areas (not illustrated) that may lie outside the array. Such circuitry may include row or column decoders, strobes (e.g., row array strobe, column array strobe), or sense amplifiers. Alternatively, such circuitry may be formed before, during, or after the formation of any one or more of the layers as illustrated in FIGS. 6 and 7.

A lid (not illustrated) with a desiccant (not illustrated) is attached to the substrate 120 at locations (not illustrated) outside the array to form a substantially completed device. A gap (not illustrated) may or may not lie between the second electrode 602 and the desiccant. The materials used for the lid and desiccant and the attaching process are conventional.

In another embodiment, the optional layer 220 can be a conductive polymer, such as a sulfonated form of PANI, PEDOT, polypyrrole, or any combination thereof. The optional layer 220 may be formed over at least portions the substrate structure 102, such as the transverse portions. The organic active layer 406, 608, 610, 612, or any combination thereof can be printed, such that it substantially prevents contact between the second electrode 602 and the optional layer 220, including over one or more transverse portions, to substantially prevent an electrical short or leakage path from forming.

3. Alternative Embodiments

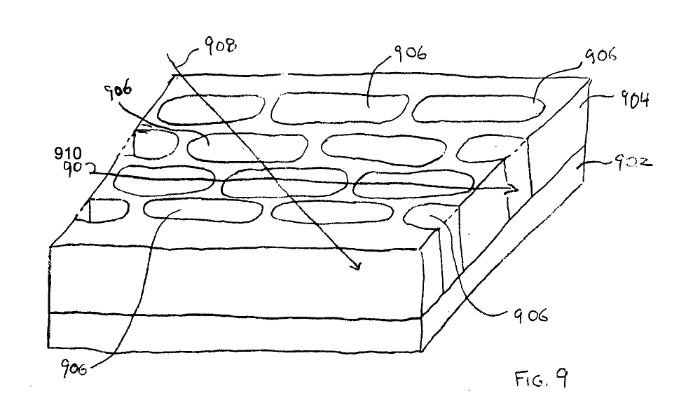

In an alternative embodiment, a workpiece 800 can include a combination of structures that can form a liquid containment structure having different heights at different locations as illustrated in FIG. 8. The liquid containment structure, including longitudinal portions and transverse portions, overlies a substrate 802 and defines openings having depths defined by the heights of the transverse portions of the liquid containment structures. The substrate 802 may or may not include electronic components or portions thereof.

In one exemplary embodiment, longitudinal portions 812 and 814 and transverse portions 806 define a set of openings 820. In one exemplary embodiment, the transverse portions 806 are substantially perpendicular to the longitudinal portions 812 and 814. In an alternative embodiment, the transverse portions are skewed from perpendicular such that each transverse portion 806 is not perpendicular to longitudinal portions 812 and 814 but still contacts both longitudinal portions 812 and 814. The set of openings 820 is included in a vector of the openings 820. The transverse portions 806 have heights that are substantially equal to one another and, as a result, the openings 820 defined by transverse portions 806 have depths that are substantially equal.

In this exemplary embodiment, a set of openings 822 is defined by longitudinal portions 814 and 816 and transverse portions 808. Transverse portions 808 have heights that are substantially equal to one another. Similarly, a set of openings 824 is defined by longitudinal portions 816 and 818 and transverse portions 810. The transverse portions 810 have substantially equal heights to one another and to the longitudinal portions 816 and 818.

In one exemplary embodiment, the transverse portions 806 and the transverse portions 808 have heights that are substantially equal to one another. In an alternative embodiment, the transverse portions 806 and the transverse portions 808 have heights that are different. In a particular embodiment, the transverse portions 806 and the transverse portions 808 have heights that are substantially equal to one another, while the transverse portions 810 have heights that are different from the heights of the transverse portions 806 and the transverse portions 808.

Such height differences between sets of transverse portions may be useful in controlling thicknesses of different materials. For example, different sets of openings may be used in forming components associated with different colors in an exemplary display within an electronic device. In one exemplary embodiment, the openings 820 are located where blue radiation-emitting components are formed, the openings 822 are located where green radiation-emitting components are formed, and the openings 824 are located where red radiation-emitting components are formed.

The longitudinal and transverse portions as illustrated in FIG. 8 can be formed by depositing one or more materials as previously described with respect to the substrate structure 102. The longitudinal and transverse portions can be deposited as one or more patterned layers or may be deposited and patterned using a conventional lithographic technique.

In one particular embodiment for an electronic device that includes an array of radiation-emitting components, a first liquid composition is printed in a line substantially parallel to and between the longitudinal portions 812 and 814, to lie within openings 820 and to at least partially overlie transverse portions 806. A second liquid composition is printed in a line substantially parallel to and between the longitudinal portions 814 and 816, to lie within openings 822 and to at least partially overlie transverse portions 808. In addition, a third liquid composition is printed in a line substantially parallel to and between the longitudinal portions 816 and 818, to lie within openings 824 and to at least partially overlie transverse portions 810. When transverse portions 806 and 808 have heights that are substantially equal to one another and are different from transverse portions 810, layers formed within openings 820 and 822 may or may not have thickness different than a layer formed within openings 824. For example, a blue light-emitting layer may be formed within openings 820, a green light-emitting layer may be formed within openings 822, and a red light-emitting layer may be formed within openings 824.

In other embodiments, other liquid compositions can be used to emit or respond to electromagnetic radiation, such as ultraviolet electromagnetic radiation, infrared electromagnetic radiation, and visible light. Liquid compositions and printing lines, including organic layer(s), which can be used for the electronic device in FIG. 8, are described earlier in this specification.

In another embodiment, structures may define vectors of offset openings. FIG. 9 includes an illustration of an exemplary pattern of openings in an exemplary structure. A structure 904 overlies a substrate 902 and defines sets of openings 906. Openings 906 located along a vector 910 may be offset from openings 906 located along vectors parallel to vector 910. For example, openings 906 may align with vectors substantially parallel to diagonal vector 908 and vectors substantially parallel to row vector 910. In this example, liquid compositions may be dispensed in vectors parallel to vector 910 or parallel to vector 908.

In still other embodiments (not illustrated), other electronic devices can be formed. For example, a passive matrix display can be formed. First electrodes can be strips having lengths substantially parallel to one another. The longitudinal portions in FIG. 8 without the transverse portions could be cathode separators. The second electrode is replaced by strips of second electrodes that have lengths substantially parallel to one another and substantially perpendicular to the strips for the first electrodes. In another embodiment, the electronic components may respond to radiation, such as radiation sensors. Radiation to or from the electronic components may be transmitted through the substrate (“bottom emission”) or through the lid (“top emission”). The positions of the first and second electrodes can be reverse, so that the cathode(s) are closer to the substrate as compared to the anode(s).

4. Advantages

In one exemplary embodiment, the processes described herein can be used to print over transverse portions and between openings located along a vector of structures without spilling liquid composition into openings located along adjacent parallel vectors.

In another exemplary embodiment, the processes described herein can be used to form lines having a continuous layer. Such continuous layers can prevent formation of leakage paths between electrodes via charge transport layers, such as those containing sulfonated versions of PEDOT or PANI.

In a further exemplary embodiment, the processes described herein can be used to provide faster processing and better line width control during formation of electronic components.

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

What is claimed is:

1. An electronic device comprising:
a substrate;
a structure overlying the substrate and defining an array of openings arranged in a set of vectors wherein, at first locations between openings along a first vector of the set of vectors, first heights at the first locations are substantially equal to one another; and
an organic layer in the geometric shape of a first line that at least partially lies within the openings along the first vector and overlies the structure at the locations between the openings along the first vector.

2. The electronic device of claim 1, wherein the structure is a well structure.

3. The electronic device of claim 1, wherein the organic layer includes an organic active layer.

4. The electronic device of claim 3, wherein the electronic device comprises a radiation-emitting component, a radiation-responsive component, or a combination thereof.

5. The electronic device of claim 1, wherein the organic layer includes a charge-injecting layer, charge-transport layer, charge-blocking layer, or any combination thereof.

6. The electronic device of claim 1, wherein, at second locations between openings along a second vector of the set of vectors, second heights at the second locations are substantially equal to one another.

7. The electronic device of claim 6, wherein the first heights and the second heights are substantially equal to one another.

8. The electronic device of claim 6, wherein the first heights are significantly different from the second heights.

9. The electronic device of claim 6, wherein the first vector and the second vector are oriented substantially perpendicular to each other.

10. The electronic device of claim 1, further comprising an electrode lying between the substrate and the structure.

11. The electronic device of claim 1, further comprising an electrode overlying the organic layer.

12. A process for forming an electronic device comprising:
forming a structure overlying a substrate, the structure defining an array of openings arranged in a set of vectors, wherein, at first locations between openings along a first vector of the set of vectors, first heights at the first locations are substantially equal to one another; and
printing a first organic layer in the geometric shape of a first line, wherein the first organic layer at least partially lies within the openings along the first vector and overlies the structure at the locations between openings along the first vector.

13. The process of claim 12, wherein the first organic layer includes an organic active layer.

14. The process of claim 12, wherein printing is performed as continuous printing using a continuous liquid dispense apparatus.

15. The process of claim 12, wherein:
the structure comprises a second vector of the set of vectors and wherein, at second locations between openings along the second vector, second heights at the second locations are substantially equal to one another;
the process further comprising continuously printing a second organic layer in the geometric shape of a second line; and
the second organic layer at least partially lies within the openings along the second vector and overlies the structure at locations between openings along the second vector.

16. The process of claim 15, wherein the first organic layer comprises a first organic active layer having an emission maximum at a first wavelength and the second organic layer comprises a second organic active layer having an emission maximum at a second wavelength different from the first wavelength.

17. The process of claim 12, wherein continuously printing the first organic layer is performed at a travel velocity of greater than 100 cm/s.

18. An electronic device comprising:
a substrate;
a first vector of openings defined by a first set of structures overlying the substrate, the first set of structures having first heights that are substantially equal to one another;
a first organic layer in the geometric shape of a first line that at least partially lies within the first vector of openings and overlies the first set of structures;
a second vector of openings defined by a second set of structures and lying substantially parallel to the first vector of openings, the second set of structures having second heights that are substantially equal to one another; and
a second organic layer in the geometric shape of a second line that at least partially lies within the second vector of openings and overlies the second set of structures.

19. The electronic device of claim 18, wherein the first heights are significantly different from the second heights.

20. The electronic device of claim 19, wherein the first organic layer comprises a first organic active layer having an emission maximum at a first wavelength, and the second organic layer comprises a second organic active layer having an emission maximum at a second wavelength different from the first wavelength.
